(19) United States
(12) Patent Application Publication
(10) Pub. No.: US 2003/0227074 A1
(43) Pub. Date: Dec. 11, 2003

(54) Semiconductor device

(76) Inventor: Tetsuya Hirano, Kanagawa (JP)

Correspondence Address: RADER FISHMAN & GRAUER PLLC, LION BUILDING, 1233 20TH STREET N.W., SUITE 501, WASHINGTON, DC, 20036, US

(21) Appl. No.: 10/420,744

(22) Filed: Apr. 23, 2003

(30) Foreign Application Priority Data
Apr. 26, 2002 (JP) P2002-125138

(51) Int. Cl. H01L 23/495; H01L 23/48

(52) U.S. Cl. 257/666; 257/673; 257/674; 257/692

(57) ABSTRACT

A semiconductor chip mounted on a flat package has two functions. The semiconductor chip has a function selecting pad supplied with a selection voltage for selecting a function. The semiconductor chip also has voltage pads for outputting function selecting voltages. Thereby the selection of a function is enabled by bonding connection such that the voltage of the voltage pad or the voltage pad is inputted to the function selecting pad via a lead frame. Thus the function can be selected and determined by the bonding connection at the time of fabrication.

### BACKGROUND OF THE INVENTION

The present invention relates to a semiconductor device, and particularly to a semiconductor device whose function to be performed is selected by voltage.

When fabricating two kinds of semiconductor devices having partially different functions, design is made such that one semiconductor device has two kinds of functions and either one of the functions can be selected at the time of fabrication.

A semiconductor device of a BGA (Ball Grid Array) package is designed such that a pad for selecting a function by voltage supplied thereto is provided on a semiconductor chip and the voltage for enabling the selected function can be supplied at the time of fabrication. FIGS. 4A and 4B are views of a semiconductor device of a BGA package, FIG. 4A shows a sectional side view, and FIG. 4B shows a fragmentary plan view with an upper package removed. As shown in FIGS. 4A and 4B, the semiconductor device 10 of the BGA package has a multilayer wiring package board 11, a semiconductor chip 12 mounted on the package board 11, and a solder ball 13 connected to a mounting board by soldering.

The package board 11 has a pad 11a for bonding connection with a bonding wire 14. The pad 11a is connected to the solder ball 13 by multilayer wiring of the package board 11. The package board 11 also has pads 11aa and 11ab for extracting a power supply voltage Vdd and a ground GND supplied to the semiconductor chip 12. The package board 11 also has a hole 11b for connecting wiring in each layer.

The semiconductor chip 12 is designed to have two functions. The semiconductor chip 12 has a pad 12a connected to the bonding wire 14, for inputting or outputting a signal. The semiconductor chip 12 also has a function selecting pad 12aa for selecting either one of the two functions. The function selecting pad 12aa is supplied with the voltage Vdd or the ground voltage GND, whereby the function is selected.

In order to select one of the functions in fabricating the semiconductor device 10 of the BGA package, the pad 11aa and the function selecting pad 12aa are connected to each other by a bonding wire 14a. In order to select the other function in fabricating the semiconductor device 10 of the BGA package, the pad 11ab and the function selecting pad 12aa are connected to each other by a bonding wire 14b (dotted line).

Thus, with the semiconductor device of the BGA package, one of the two kinds of functions can be selected by bonding connection at the time of fabrication of the semiconductor device. Incidentally, fabricating two different kinds of semiconductor devices by bonding connection is described as bonding option.

In contrast to the semiconductor device of the BGA package, a semiconductor device of for example a flat package or the like without a multilayer wiring board is designed such that voltage for selecting a function is inputted from a lead frame when the semiconductor device is mounted on a mounting board. FIGS. 5A and 5B are views of a semiconductor device of a flat package, FIG. 5A shows a sectional side view, and FIG. 5B shows a fragmentary plan view with an upper package removed. As shown in FIGS. 5A and 5B, the semiconductor device 20 of the flat package has a package 21, a semiconductor chip 22, and a lead frame 23 fixed to the package 21, for inputting or outputting a signal of the semiconductor chip 22 from or to the outside.

The semiconductor chip 22 is designed to have two functions. The semiconductor chip 22 has a pad 22a connected to a bonding wire 24, for inputting or outputting a signal. The semiconductor chip 22 also has a function selecting pad 22aa for selecting either one of the two functions. The function selecting pad 22aa is supplied with a voltage Vdd or a ground voltage GND, whereby the function is selected. The function selecting pad 22aa is connected to a lead frame 23a by a bonding wire 24a.

In order to select one of the functions in using the semiconductor device 20 of the flat package, the voltage Vdd is supplied to the lead frame 23a from the mounting board when the semiconductor device 20 is mounted on the mounting board. In order to select the other function in using the semiconductor device 20 of the flat package, the ground voltage GND is supplied to the lead frame 23a from the mounting board.

Thus, in the case where the semiconductor device is without a multilayer board, the voltage to be supplied to the lead frame is determined at the time of mounting the semiconductor device onto the mounting board, whereby one of the two kinds of functions is selected and used.

However, when the semiconductor device as described above is used in an electronic apparatus, it is concerned that the semiconductor device may be used in a manner different from original specifications of the electronic apparatus by isolating the lead frame from the mounting board and inputting a voltage for changing the function of the semiconductor device. Thus, there is a desire for a semiconductor device that allows a function thereof to be selected and determined by bonding connection at the time of fabrication.

### SUMMARY OF THE INVENTION

The present invention has been made in view of the above, and it is accordingly an object of the present invention to provide a semiconductor device that allows a function thereof to be selected and determined at the time of fabrication.

According to the present invention, there is provided a semiconductor device for selecting a function to be performed by voltage, including: a semiconductor chip having a function selecting pad supplied with one of a first selection voltage or a second selection voltage for selecting a function, a first voltage pad for outputting the first selection voltage, and a second voltage pad for outputting the second selection voltage; and a lead frame bonding-connected to one of the first voltage pad or the second voltage pad and bonding-connected to the function selecting pad, for inputting one of the first selection voltage and the second selection voltage to the function selecting pad.

With such a semiconductor device, the semiconductor chip has the function selecting pad, the first voltage pad, and the second voltage pad, and the first selection voltage of the first voltage pad or the second selection voltage of the second voltage pad is inputted to the function selecting pad by bonding connection thereof with the lead frame. It is therefore possible to select and determine the function at the time of fabrication.

### BRIEF DESCRIPTION OF THE DRAWINGS

FIG. 1 is a plan view of a semiconductor device according to the present invention with an upper part of a flat package removed;

FIG. 2 is a sectional view of the semiconductor device of FIG. 1;

FIG. 3 is an enlarged view of a function selecting pad and voltage pads in FIG. 1 and a vicinity thereof;

FIGS. 4A and 4B are views of a semiconductor device of a BGA package, FIG. 4A shows a sectional side view, and FIG. 4B shows a fragmentary plan view with an upper package removed; and

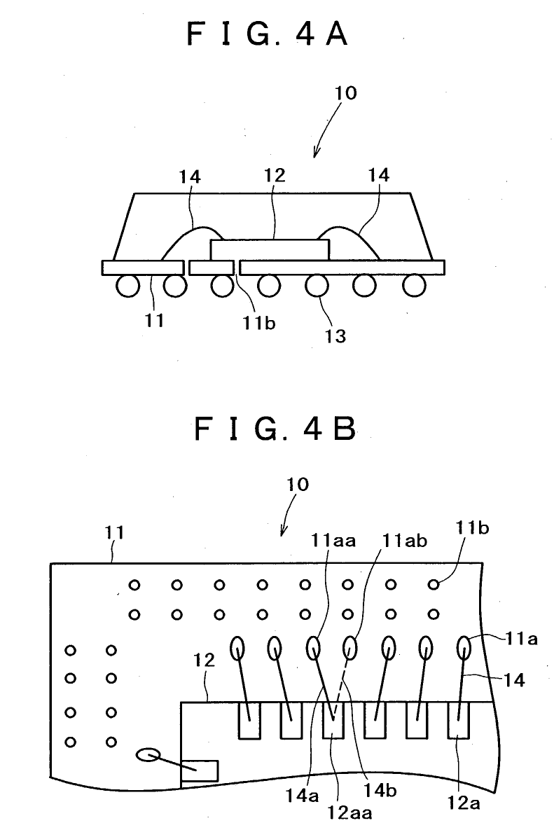

FIGS. 5A and 5B are views of a semiconductor device of a flat package, FIG. 5A shows a sectional side view, and FIG. 5B being a fragmentary plan view with an upper package removed.

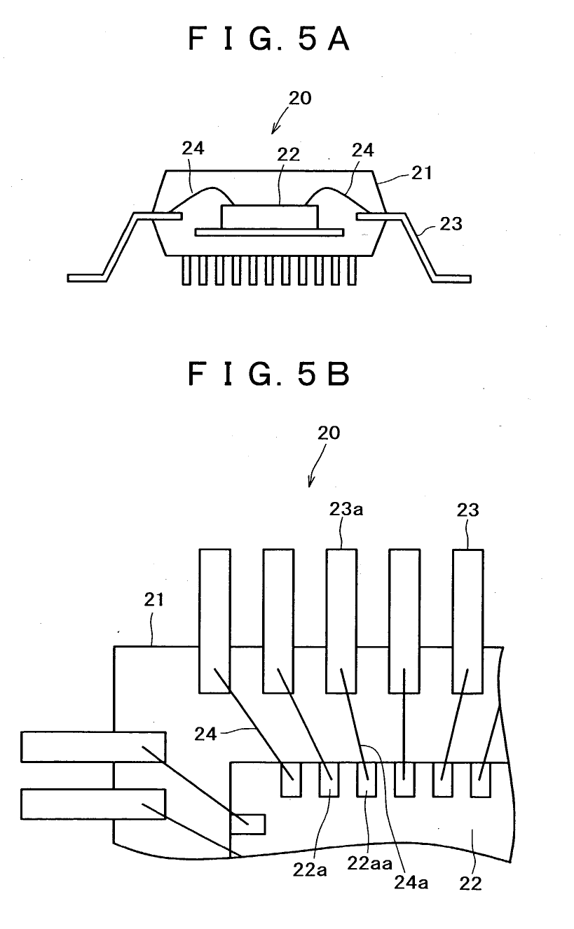

### DETAILED DESCRIPTION OF THE PREFERRED EMBODIMENT

A preferred embodiment of the present invention will hereinafter be described with reference to the drawings.

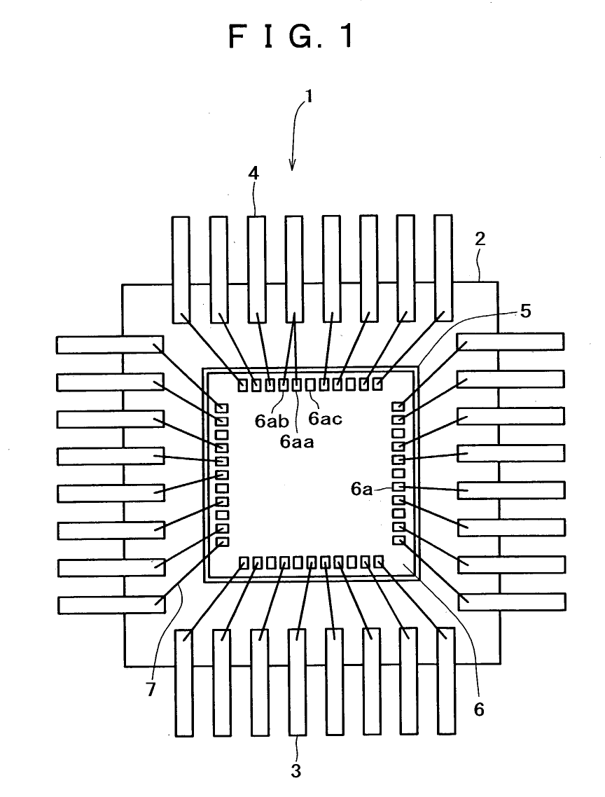

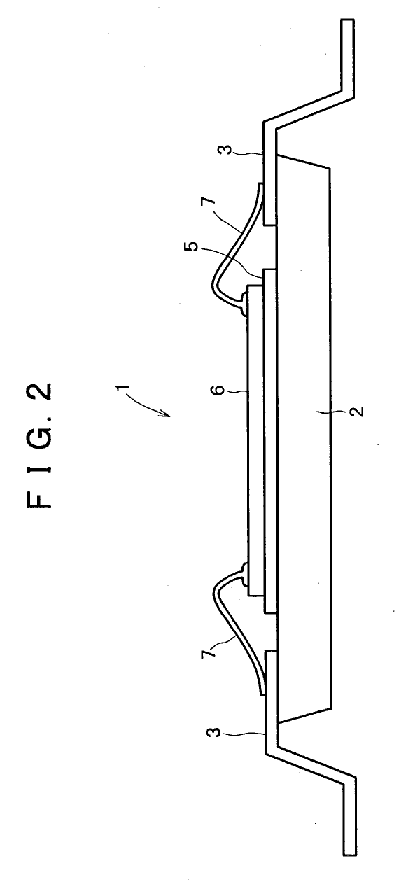

FIG. 1 is a plan view of a semiconductor device according to the present invention with an upper part of a flat package removed. FIG. 2 is a sectional view of the semiconductor device of FIG. 1. As shown in FIG. 1 and FIG. 2, the semiconductor device 1 has: a flat package 2: a lead frame 3 fixed to the flat package 2, for inputting or outputting a signal from a mounting board; a lead frame 4 fixed to the flat package 2, for use in selecting a function of the semiconductor device 1; a mount 5 fixed on an upper surface of the flat package 2; and a semiconductor chip 6 designed to have two functions A and B and mounted on the mount 5.

The semiconductor chip 6 has pads 6a provided on a periphery thereof for inputting and outputting signals. A pad 6a is bonding-connected to the lead frame 3 by a bonding wire 7. The semiconductor chip 6 also has a function selecting pad 6aa supplied with a selection voltage for selecting the function A or B and voltage pads 6ab and 6ac for outputting voltage for selecting functions.

A layout of the semiconductor chip 6 is designed such that a power supply voltage Vdd and a ground GND supplied to the semiconductor chip 6 are outputted to the voltage pads 6ab and 6ac at the time of mounting the semiconductor device 1 onto the mounting board. It is assumed that the semiconductor chip 6 performs the function A when the voltage Vdd is supplied to the function selecting pad 6aa, and that the semiconductor chip 6 performs the function B when the ground GND is supplied to the function selecting pad 6aa.

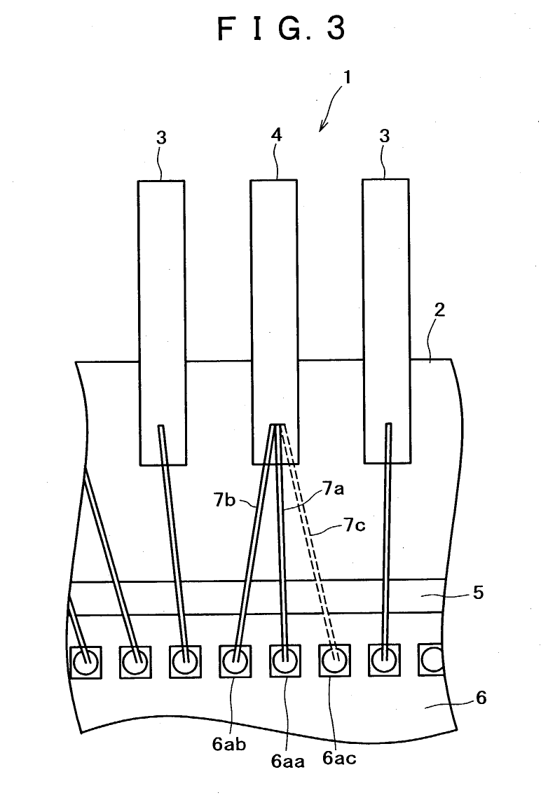

FIG. 3 is an enlarged view of the function selecting pad and the voltage pads in FIG. 1 and a vicinity thereof. As shown in FIG. 3, when the semiconductor device 1 is fabricated to have the function A, at the time of the fabrication, the lead frame 4 and the function selecting pad 6aa are bonding-connected to each other by a bonding wire 7a, and further the voltage pad 6ab and the lead frame 4 are bonding-connected to each other by a bonding wire 7b. Thereby, when the semiconductor device 1 is mounted on the mounting board, the voltage Vdd is supplied to the function selecting pad 6aa, and hence the semiconductor device 1 performs the function A.

When the function B is selected in fabricating the semiconductor device 1, at the time of the fabrication, the lead frame 4 and the function selecting pad 6aa are bonding-connected to each other by the bonding wire 7a, and further the voltage pad 6ac and the lead frame 4 are bonding-connected to each other by a bonding wire 7c (dotted line). Thereby, when the semiconductor device 1 is mounted on the mounting board, the ground GND is supplied to the function selecting pad 6aa, and hence the semiconductor device 1 performs the function B.

Thus, the function of the semiconductor device according to the present invention can be selected and determined by the bonding connection at the time of the fabrication.

Further, with an electronic apparatus incorporating the semiconductor device, it is possible to prevent change in specifications of the electronic apparatus through unauthorized functional change by a user who purchased the electronic apparatus, for example.

Incidentally, since the lead frame connected to the function selecting pad is a non-connection lead frame, the lead frame does not need to be extended to the outside of the flat package, and the lead frame may be formed to be of such a size as to be housed inside the package, and fixed.

As described above, according to the present invention, the semiconductor chip has the function selecting pad, the first voltage pad, and the second voltage pad, and the first selection voltage of the first voltage pad or the second selection voltage of the second voltage pad is inputted to the function selecting pad by bonding connection thereof with the lead frame. It is thereby possible to select and determine the function at the time of fabrication.

Since the above description of the preferred embodiments is for illustrative purposes only, and it is to be understood that changes and variations may be made without departing from the spirit or scope of the following claims.

What is claimed is:

1. A semiconductor device for selecting a function to be performed by voltage, comprising:
a semiconductor chip having a function selecting pad supplied with one of a first selection voltage or a second selection voltage for selecting a function, a first voltage pad for outputting said first selection voltage, and a second voltage pad for outputting said second selection voltage; and
a lead frame bonding-connected to one of said first voltage pad or said second voltage pad and bonding-connected to said function selecting pad, for inputting one of said first selection voltage or said second selection voltage to said function selecting pad.

2. A semiconductor device as claimed in claim 1,
wherein said first selection voltage and said second selection voltage are a positive power supply voltage and a negative power supply voltage supplied to said semiconductor chip.
